(19) United States
(12) Patent Application Publication
(10) Pub. No.: US 2026/0086908 A1
(43) Pub. Date: Mar. 26, 2026

(54) HANDLING OF OPERATIONAL METRICS IN RESOURCE-LIMITED DEVICES AND COMMUNICATION SYSTEMS

(71) Applicant: Sensus Spectrum, LLC, Morrisville, NC (US)

(72) Inventor: Adam Hansen, Cary, NC (US)

(21) Appl. No.: 18/893,362

(22) Filed: Sep. 23, 2024

(51) Int. Cl. G06F 11/30; G01R 31/392

(52) U.S. Cl. CPC G06F 11/3058; G01R 31/392

(57) ABSTRACT

Some aspects of the inventive concept relate to techniques that can be used for managing operational metrics in resource-limited devices. These techniques can include obtaining multiple measurements of an operational metric over time, with each measurement falling within a predetermined overall range. The measurements can be aggregated into predefined data bins, each corresponding to a specific sub-range. A count can be determined for each data bin, generating distribution data that represents the distribution of the metric over time. The distribution data can be encoded into a communication message by mapping it to specific positions within the message, according to a predefined mapping policy. This allows the distribution of the operational metric to be determined based on the received message and the mapping policy.

### FIELD

The present disclosure generally relates to the management of operational metrics and, more particularly, to the handling, encoding, and/or transmission of operational metrics in resource-limited devices and communication systems.

### BACKGROUND

Many battery-operated devices, such as those used in utility monitoring and measurement applications, are designed to operate for extended periods, often exceeding 10 or 20 years, without the need for battery replacement or recharging. The performance and longevity of these batteries can be significantly influenced by the operational metrics they encounter throughout their deployment. Traditionally, battery life estimates have relied on generalized or estimated data, such as temperature readings from the National Weather Service. However, these estimates may not accurately reflect the specific conditions experienced by the field device. For instance, external temperature data may not consider factors like the field device's installation environment, or exposure to direct sunlight or shade.

Direct measurement of these operational metrics can provide a more accurate basis for predicting battery life, which can be useful for planning, maintenance, and managing warranties. However, capturing and transmitting this data poses substantial challenges. While frequent measurements may be ideal for understanding how these metrics change over time, the energy required for frequent data transmissions can rapidly deplete the battery, which is expected to last for many years. Additionally, these devices often communicate using low-bandwidth protocols, which can limit the amount of data that can be transmitted, further complicating the task of sending detailed information within the available resource constraints.

### SUMMARY

Some aspects of the inventive concept relate to techniques that can be used for managing operational metrics in resource-limited devices. These techniques can include obtaining multiple measurements of an operational metric over time, with each measurement falling within a predetermined overall range. The measurements can be aggregated into predefined data bins, each corresponding to a specific sub-range. A count can be determined for each data bin, generating distribution data that represents the distribution of the metric over time. The distribution data can be encoded into a communication message by mapping it to specific positions within the message, according to a predefined mapping policy. This allows the distribution of the operational metric to be determined based on the received message and the mapping policy.

Certain illustrative examples are described in the following numbered clauses:
Clause 1. A system comprising a device, the device comprising a processor configured to:
obtain a plurality of measurements of an operational metric captured by a sensor, wherein the sensor captures the plurality of measurements over time, and wherein the plurality of measurements fall within an overall range for the operational metric;
aggregate the plurality of measurements into data bins, each data bin corresponding to a different sub-range of the overall range of the operational metric, wherein each measurement is assigned to a respective data bin based on a respective sub-range it corresponds to;
determine a value representing a count of measurements for each data bin, thereby generating distribution data that represents a distribution of the operational metric over the time;
encode the distribution data into a communication message by mapping portions of the distribution data to specific positions within the communication message according to a mapping policy, wherein the mapping policy assigns a different predetermined position in the communication message to the respective distribution data of each data bin, such that the value for each data bin is assigned to a unique position within the communication message; and
make the communication message available for transmission or retrieval, wherein the distribution of the operational metric over the time can be determined based on the communication message and the mapping policy.
Clause 2. The system of clause 1, wherein the operational metric is at least one of temperature, flow rate, pressure, level, velocity, acceleration, power, or usage patterns.
Clause 3. The system of any of the preceding clauses, wherein the processor is further configured to dynamically adjust the data bins based on a concentration of measurements within specific sub-ranges of the overall range for the operational metric.
Clause 4. The system of any of the preceding clauses, wherein there are multiple configurations of data bins, each configuration corresponding to different predefined ranges for the operational metric, wherein the processor is further configured to select a configuration of data bins based on the plurality of measurements, and encode a configuration identifier of the selected configuration into the communication message based on the mapping policy.
Clause 5. The system of any of the preceding clauses, wherein the processor is further configured to encode the distribution data into the communication message based on a predefined bin configuration, wherein the predefined bin configuration specifies that ranges of the operational metric and their corresponding positions within the communication message are established before the processor begins encoding the distribution data.
Clause 6. The system of any of the preceding clauses, wherein each data bin is assigned to a different location within the communication message, such that the value representing the measurements for each data bin is stored in a unique location of the communication message.
Clause 7. The system of any of the preceding clauses, wherein the communication message includes a configuration identifier, and the processor is configured to encode the configuration identifier within the communication message, specifying whether the predefined data bins are uniform or non-uniform.
Clause 8. The system of any of the preceding clauses, wherein the processor is further configured to include, within the communication message, an identifier corresponding to each predefined range of the operational metric and a corresponding count, wherein specific ranges included in the communication message vary based on data collected.
Clause 9. The system of any of the preceding clauses, wherein the processor is further configured to encode at least one of actual start values or actual end values of each range of the operational metric within the communication message, along with a corresponding count for each range.
Clause 10. The system of clause 9, wherein the communication message includes a sequence of values, where each sequence of values encodes at least one of a start value or an end value, and a count for each range of the operational metric.
Clause 11. The system of any of the preceding clauses, further comprising a battery configured to provide power to a device for an extended duration without recharge, wherein the operational metric relates to a remaining life of the battery, and wherein the remaining life of the battery is estimated based at least in part on the communication message.
Clause 12. The system of any of the preceding clauses, wherein the processor is further configured to assign multiple different types of operational metrics to specific data bins within the communication message, and to encode a configuration identifier that specifies a type of operational metric stored in each data bin, allowing for transmission of multiple different operational metrics in a single communication message.
Clause 13. A method, comprising:
obtaining a plurality of measurements of an operational metric captured by a sensor, wherein the sensor captures the plurality of measurements over time, and wherein the plurality of measurements fall within an overall range for the operational metric;
aggregating the plurality of measurements into predefined data bins, each data bin corresponding to a different sub-range of the overall range of the operational metric, wherein each measurement is assigned to a respective data bin based on a respective sub-range it corresponds to;
determining a value representing a count of measurements for each data bin, thereby generating distribution data that represents a distribution of the operational metric over the time;
encoding the distribution data into a communication message by mapping portions of the distribution data to specific positions within the communication message according to a mapping policy, wherein the mapping policy assigns a different predetermined position in the communication message to the respective distribution data of each data bin, such that the value for each data bin is assigned to a unique position within the communication message; and
transmitting the communication message over a communication protocol, wherein the distribution of the operational metric over the time can be determined based on the communication message and the mapping policy.
Clause 14. The method of clause 13, further comprising dynamically adjusting the predefined data bins based on a concentration of measurements within specific sub-ranges of the overall range for the operational metric.
Clause 15. The method of any of clauses 13 or 14, further comprising selecting a configuration of data bins from multiple configurations, each configuration corresponding to different predefined ranges for the operational metric, and encoding a configuration identifier of the selected configuration into the communication message based on the mapping policy.
Clause 16. The method of any of clauses 13 to 15, further comprising assigning multiple different types of operational metrics to specific data bins within the communication message, and encoding a configuration identifier that specifies the type of operational metric stored in each data bin, thereby allowing for transmission of multiple different operational metrics in a single communication message.
Clause 17. A method for processing received operational metrics, the method comprising:
receiving a communication message from a field device, wherein the communication message corresponds to aggregated distribution data representing a plurality of measurements of an operational metric captured by the field device, the measurements having been aggregated into predefined data bins, each data bin corresponding to a sub-range of an overall range of the operational metric;
identifying a mapping policy associated with the communication message, wherein the mapping policy defines specific positions within the communication message for respective portions of the distribution data;
extracting the distribution data and the scalar identifier from the communication message based on the mapping policy, wherein a value of each data bin is obtained from an assigned position within the communication message;
determining the distribution of the operational metric over time based on the extracted distribution data and the respective sub-ranges of the data bins; and
analyzing the determined distribution to assess operational conditions, predict maintenance requirements, or adjust operational parameters for the field device.
Clause 18. The method of clause 17, wherein the distribution data corresponds to a temperature of a field device, and further comprising using the distribution data to determine an expected remaining battery life of the field device.
Clause 19. The method of any of clauses 17 or 18, wherein the mapping policy includes a configuration identifier, the method further comprising identifying a configuration of data bins in the communication message based on the configuration identifier, wherein the configuration identifier specifies at least one of a structure or an arrangement of the data bins.
Clause 20. The method of any of clauses 17 to 20, further comprising adjusting interpretation of the distribution data based on a compression component identified within the communication message, wherein the compression component is applied to the values to reconstruct an original count of measurements for each data bin.

### BRIEF DESCRIPTION OF THE DRAWINGS

Throughout the drawings, reference numbers can be re-used to indicate correspondence between referenced elements. The drawings are provided to illustrate embodiments of the present disclosure and do not to limit the scope thereof.

FIG. 1 illustrates a block diagram of a system for handling operational metrics in resource-limited devices.

FIG. 2 illustrates an example data structure of a communication message configured to transmit operational metrics from a field device.

FIG. 3 presents a flow diagram illustrating an embodiment of a routine implemented by the field device of FIG. 1.

FIG. 4 presents a flow diagram illustrating an embodiment of a routine implemented by the interpretation and management system of FIG. 1.

### DETAILED DESCRIPTION

Monitoring and managing the performance of battery-operated devices used in utility and measurement applications can be important for maintaining the reliability and efficiency of these systems over extended periods. Traditionally, predicting battery life in these devices has relied on estimates derived from generalized operational metrics, such as temperature data from external sources. However, these estimates may not accurately reflect the specific environmental conditions experienced by the field device, leading to potential inaccuracies in battery life predictions. This limitation highlights the need for more precise techniques for capturing and transmitting operational metrics while conserving battery life and communication bandwidth.

Some inventive concepts described herein can improve the management of operational metrics in battery-operated devices by enabling these devices to efficiently collect, aggregate, and transmit data. For example, each device can obtain multiple measurements of an operational metric, such as temperature, over time. These measurements can be aggregated into predefined data bins, each representing a sub-range of the overall metric range. By encoding this aggregated data into a communication message according to a mapping policy, the field device can transmit the information over a low-bandwidth communication protocol. This approach can allow the distribution of the operational metric to be determined accurately while reducing the energy and bandwidth required for data transmission.

In some embodiments, processing of the operational metrics can be performed directly by the field device, which can reduce a need for frequent data transmissions. By conducting data aggregation and analysis internally, the field device can transmit more comprehensive and informative updates, thereby conserving battery life and reducing data usage, rather than more frequent, smaller transmissions. Such a technique can be advantageous, for example, in scenarios where activating a transceiver for communication is energy-intensive, as it can reduce the frequency of such activations. Similarly, in wired connections, it can reduce the frequency of data transmissions, thereby conserving overall system resources.

Some inventive concepts described herein can accommodate the collection and transmission of multiple operational metrics. In such cases, the field device can aggregate data from several metrics, such as temperature, pressure, and flow rate, and encode them into a single communication message. This capability can make more efficient use of available bandwidth by allowing multiple metrics to be transmitted together, further reducing the energy required for data transmission and facilitating the effective conveyance of detailed operational information.

Some inventive concepts described herein relate to systems that can more effectively convey the distribution of operational metrics by utilizing direct measurements. These systems can allow the field device to adjust the configuration of data bins based on the range and concentration of measurements collected. For example, if a large percentage of measurements fall within a specific range, the field device can reconfigure the data bins to provide a more detailed breakdown of that range, thereby offering the receiver a more nuanced understanding of the data distribution. This approach can improve the relevance and accuracy of the transmitted data, aiding in better analysis, planning, and decision-making related to the field device's operation and maintenance.

Some inventive concepts described herein can include methods for managing the transmission of operational metric data within the constraints of low-bandwidth communication protocols. The system can aggregate the data into predefined data bins that represent the distribution of the operational metrics over a given range. By mapping these aggregated data portions, which summarize the frequency or proportion of metrics within each data bin, to specific positions within the communication message, the system can effectively convey the distribution of the data while conserving battery life and maintaining the integrity of the transmitted information. The mapping policy used for encoding this distribution data can either be known by the receiver in advance or embedded within the communication message itself, allowing the receiver to accurately interpret the summarized distribution of the operational metrics. This method of data handling can represent an advancement in the field, particularly for devices that must operate reliably over long periods with limited resources.

Some inventive concepts described herein can offer improvements in the management of battery-operated devices used in various utility and measurement applications. By enabling these devices to efficiently handle, encode, and transmit operational metrics, the disclosed techniques can enhance the accuracy of battery life predictions while conserving energy and communication resources. These advancements can provide a more practical approach to managing the long-term performance of such devices in resource-constrained environments.

### Environment Overview

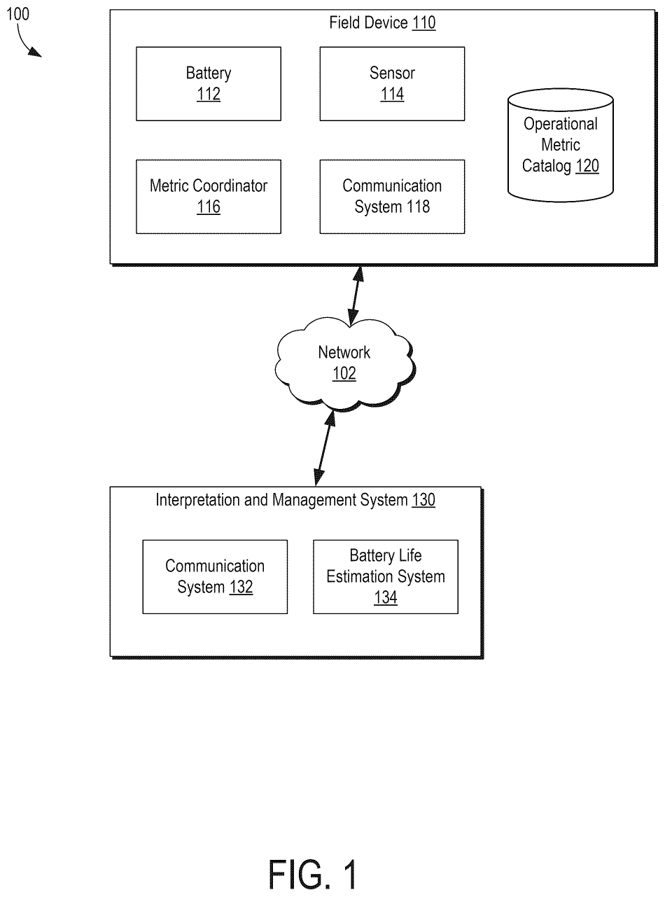

FIG. 1 illustrates a block diagram of a system 100 for handling operational metrics in resource-limited devices. The system 100 includes a field device 110, an interpretation and management system 130, and a network 102 that facilitates communication between them. The field device 110 is configured to monitor, process, and transmit operational metrics, such as temperature, in environments where resources like power and bandwidth are limited. The interpretation and management system 130 receives and analyzes the data transmitted by the field device 110. To simplify the discussion and not to limit the present disclosure, FIG. 1 illustrates only one field device 110 and one interpretation and management system 130, though multiple such components may be used.

Any of the foregoing components or systems of the system 100 may communicate via the network 102. Although only one network 102 is illustrated, multiple distinct and/or distributed networks 102 may exist. The network 102 can include any type of communication network, including wireless and wired communication protocols. For example, the network 102 can include, but is not limited to, local area networks (LAN), wide area networks (WAN), cellular networks, satellite networks, or wireless networks, such as Internet Protocol (IP) networks. In some embodiments, the network 102 can include the Internet or other wide-reaching communication systems. The network 102 can include radio frequency (RF) communication.

The network 102 can operate under conditions of restricted or limited bandwidth, which can influence the volume of data transmissions. In some embodiments, the network 102 can impose a fixed payload size, constraining each communication message to a size limit, such as 16, 28, 32, 48, 64, 128, or 256 bytes. Bandwidth restrictions can be encountered in low-data-rate communication protocols, such as those used in radio frequency (RF) systems, satellite networks, or other specialized communication infrastructures. In some cases, the network 102 can necessitate the use of compact, optimized data formats to conform to these size limits.

Any of the foregoing components or systems of the system 100, such as any one or any combination of the field device 110 and the interpretation and management system 130, may be implemented using individual computing devices, processors, distributed processing systems, servers, isolated execution environments (e.g., virtual machines, containers, etc.), shared computing resources, embedded device, or so on. Furthermore, any of the foregoing components or systems of the system 100 may be combined and/or may include software, firmware, hardware, or any combination(s) of software, firmware, or hardware suitable for the purposes described.

The field device 110 can be a utility metering or monitoring device used in applications such as water, gas, or electricity metering. For example, the field device 110 can include, but is not limited to, a smart water meter, an electricity meter, a gas meter, or an environmental monitoring sensor. The field device 110 can be configured to capture operational metrics, such as usage data, and transmit this information to utility companies. The field device 110 can be configured to operate for extended periods, efficiently handling the collection and transmission of data. These devices provide reliable data that supports monitoring usage patterns, managing resources, and maintaining accurate billing.

The battery 112 can be configured to provide power to the field device 110, enabling operation over extended periods without requiring frequent recharging or replacement. The battery 112 is designed to support continuous or sporadic operation of various components within the field device 110, including sensors 114, the metric coordinator 116, and the communication system 118. While the battery 112 does not directly interact with operational metrics, performance and longevity can be influenced by environmental conditions under which the field device 110 operates. In some cases, the field device 110 can remain in a low-power sleep state for the majority of its operational time, with most components powered off. In some such cases, the field device 110 may wake periodically to sample sensors or perform tasks, or can be triggered by asynchronous events to resume operation when necessary. In some cases, the field device 110 may not include a battery 112, such as when the field device 110 is implemented as an electricity meter, which typically operates without batteries. It will be appreciated the inventive concepts still apply in devices that do not rely on batteries.

The expected life of the battery 112 can be calculated based on operational metrics captured by sensors 114 and processed by the metric coordinator 116 or the interpretation and management system 130. For instance, metrics such as temperature, power consumption, and usage patterns can be monitored to assess impact on battery life. Actual performance of the battery 112 can be compared to these expected values to provide a more accurate prediction of remaining battery life. This prediction can be periodically updated as new data is collected, allowing the field device 110 to adjust operation to conserve power and extend battery life. Expected battery life may indicate when the battery 112 is approaching the end of expected life, facilitating timely maintenance or replacement.

The sensors 114 can be configured to capture a range of operational metrics, such as temperature, pressure, flow rate, or utility consumption data, depending on the specific application of the field device 110. In some cases, these metrics can have a direct impact on the performance and longevity of the battery 112, as environmental factors like temperature and power usage can affect the rate of battery discharge. The sensors 114 continuously or periodically monitor these metrics, providing real-time data to the metric coordinator 116 for further processing.

The sensors 114 are designed to provide data that is accurate and relevant for specific operational conditions of the field device 110. For example, in environments where the field device 110 is exposed to varying temperatures, sensors 114 can provide precise temperature readings for calculating battery life and assessing overall device performance. Sensors 114 can be designed to operate with low power consumption, contributing to the energy efficiency of the field device 110. In some embodiments, multiple sensors 114 may be employed to monitor different environmental parameters, such as humidity, pressure, and vibration, thereby providing a data set for analysis and improving accuracy of battery life predictions.

The metric coordinator 116 can be responsible for aggregating and organizing data collected by the sensors 114, preparing it for transmission through the communication system 118. The metric coordinator 116 can process raw data by grouping it into predefined data bins that represent different ranges of the operational metrics. This aggregated data can then be encoded into a communication message according to a mapping policy, allowing the data to be transmitted efficiently, even under constraints such as limited bandwidth or fixed payload sizes.

The metric coordinator 116 can be configured to adjust the configuration of data bins based on the range and concentration of measurements collected by the sensors 114. For instance, if a large percentage of measurements fall within a specific range, the metric coordinator 116 may reconfigure data bins to provide a more detailed breakdown of that range, offering the receiver a more nuanced understanding of the data distribution. This capability can enhance the accuracy and relevance of the data transmitted by the field device 110, supporting better decision-making and analysis on the receiving end.

The metric coordinator 116 can manage the timing and frequency of data transmissions. By analyzing operational metrics and the status of the battery 112, the metric coordinator 116 can determine intervals for data transmission, balancing the need for up-to-date information with the conservation of battery life. This methodical approach to data management can enable the field device 110 to operate efficiently within the constraints of the communication protocol while providing reliable and actionable data to external systems.

The communication system 118 can be responsible for managing the transmission of processed data from the field device 110 to external systems, such as utility company servers. The communication system 118 can be implemented using various network protocols, including both wired and wireless communication methods. In some embodiments, the communication system 118 can be implemented as a radio module, specifically designed for transmitting data in utility metering applications. For example, communication system 118 may be a SmartPoint™ module, sold by Sensus USA Inc., whose headquarters are located in Raleigh, North Carolina.

The communication system 118 can handle constraints imposed by the network 102, such as limited bandwidth and fixed payload sizes. The communication system 118 can encode aggregated data from the metric coordinator 116 into a format compatible with the network's requirements, enabling data to be transmitted effectively within the available bandwidth. In some cases, the communication system 118 can manage transmission frequency, adapting to operational conditions and the status of the battery 112 to optimize data transmission and extend the operational life of the field device 110.

The operational metric catalog 120 can store or reference data collected by the sensors 114, maintaining a historical record of operational metrics. The operational metric catalog 120 can include data on past measurements, as well as reference ranges or thresholds relevant to the specific application of the field device 110. The operational metric catalog 120 can support the metric coordinator 116 by providing context for data being processed, such as historical trends or anomalies that might affect the interpretation of current measurements.

The operational metric catalog 120 can assist in the adjustment of data bins and mapping policies used by the metric coordinator 116. By referencing historical data, the metric coordinator 116 can adjust the configuration of the data bins to reflect the most relevant and up-to-date operational conditions. This process can ensure that data transmitted by the field device 110 is accurate, relevant, and appropriately detailed for the receiving system's analysis and decision-making processes.

The interpretation and management system 130 can receive and analyze data transmitted by the field device 110. The interpretation and management system 130 can include a communication system 132, which handles the reception and processing of incoming communication messages. The communication system 132 can be configured to manage incoming data streams under various network conditions, ensuring that data is received intact and processed efficiently. The interpretation and management system 130 can include a battery life estimation system 134, which can analyze the received operational metrics, such as temperature distributions, to estimate the remaining battery life of the field device 110. The battery life estimation system 134 can utilize complex algorithms and models that account for the specific conditions experienced by the field device 110, using actual temperature data rather than estimated values to provide more accurate predictions. These predictions can inform decisions regarding maintenance schedules, battery replacement, and overall operational strategies, ensuring that the field device 110 remains functional and reliable over its intended lifespan.

### Example Data Structure of a Communication Message

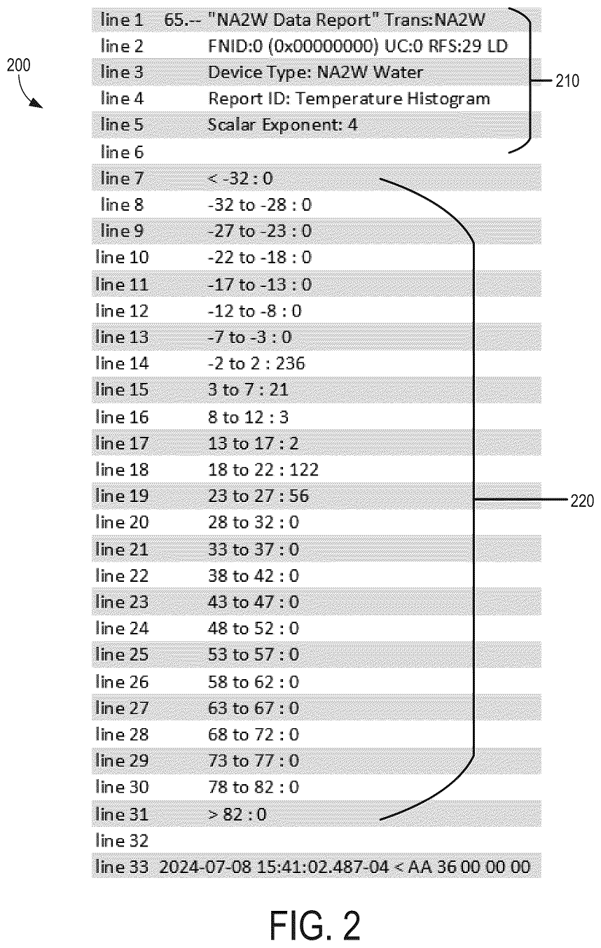

FIG. 2 illustrates an example data structure of a communication message 200 configured to transmit operational metrics, specifically a temperature histogram, from a field device. The communication message 200 can be structured to include various fields, each occupying a specific position within the communication message, potentially corresponding to some number of bits or bytes. The structure of the communication message 200 can allow for the organized transmission of detailed operational data, ensuring that each piece of information is accurately conveyed within the constraints of the communication protocol.

The communication message 200 can begin with a header section 210, which can include several identifiers that provide context for the communication message. The header section 210 can include a report identifier, which can specify the type of report being transmitted, such as a “Temperature Histogram.” In some cases, header section 210 can include a transmission identifier to indicate the specific transmission event or sequence, facilitating the tracking and organization of incoming data streams by the receiving system. In some cases, header section 210 can include a field device type identifier, indicating the type of device from which the operational metrics were obtained, such as a “NA2W Water” device. In some cases, header section 210 can include a scaling factor or other means of compression, such as a scalar exponent (e.g., “4”), which can represent a scaling component used to compress the counts of temperature measurements within each data bin. For example, a scalar exponent of 4 can imply that each count represents 2^4 (or 16) actual measurements, allowing the data to be compressed effectively for transmission. It will be appreciated that the scalar exponent is merely one example of a scaling factor, and other methods of data compression can similarly be employed to fit data into the communication message.

The main body 220 of the communication message 200 can include the distribution data, which, in this example, can represent the aggregated temperature measurements categorized into predefined data bins. Each data bin can correspond to a specific temperature range, such as “<−32° C.,” “−32° C. to −28° C.,” and so forth. The value assigned to each data bin can indicate the number of measurements that fall within that temperature range. These values can be scaled by the scalar exponent to reflect the actual number of measurements. For instance, a bin value of “236” in the “−2° C. to 2° C.” range can translate to 236*16=3,776 measurements. This structured approach to organizing distribution data can allow the communication message to convey a comprehensive snapshot of the temperature data while maintaining an efficient use of the available bandwidth.

The communication message 200 can also include a timestamp (line 33) that records the date and time when the data was collected or transmitted. The inclusion of the timestamp can provide a temporal reference for the measurements, enabling a receiving system to align the data with other time-sensitive information accurately.

In some cases, the communication message 200 can include hexadecimal values representing additional data or control information used by the communication protocol. These values can help manage the transmission process, ensuring that the communication message is received and interpreted correctly by the receiving system.

The structure of the communication message 200 can be designed to balance the need for detailed operational data with the practical limitations of bandwidth and processing capacity. By leveraging a predefined mapping policy, each component of the communication message—whether it is an identifier, a data bin, or a timestamp—can be mapped to a specific position within the communication message. This systematic arrangement can allow the receiving system to reconstruct the original temperature distribution accurately, ensuring that the operational metrics are conveyed effectively even within the constraints of a limited-bandwidth communication environment.

### Handling and Transmission of Operational Metrics in Resource-limited Devices

In various applications, such as utility metering and environmental monitoring, battery-operated field devices are expected to function over extended periods, often spanning decades, without the need for recharging or replacement. These field devices frequently operate in environments where temperature variations can affect battery performance and longevity. Traditional methods for estimating battery life often rely on external temperature data, which may not accurately reflect the conditions around each individual field device. Factors such as exposure to sunlight or shade, and the physical characteristics of the field device, can influence the local temperature. Therefore, actual temperature measurements taken by the field device can provide a more representative basis for assessing battery life.

Some inventive concepts herein relate to methods for efficiently obtaining and transmitting temperature measurements to support battery life estimation, considering the constraints of low power consumption and/or limited communication bandwidth. Such techniques can include logging temperature readings over time, organizing these readings into a set of predefined data bins, and/or transmitting the aggregated distribution data in a compact communication message. For example, the distribution data might be represented as a histogram, where each data bin corresponds to a specific range of temperatures, and the distribution within each data bin provides a summary of the temperature conditions over time. Such approaches can facilitate the collection and communication of temperature data while managing energy consumption and adhering to a low-bandwidth communication protocol.

Although the disclosed techniques are generally discussed relative to temperature measurements, it will be appreciated that these approaches can be applied to any metric where knowledge of that metric over time is beneficial and/or where the metric typically remains within a given range. Examples include, but are not limited to, flow rate, pressure, level, velocity, acceleration, power, usage patterns, or other similar metrics.

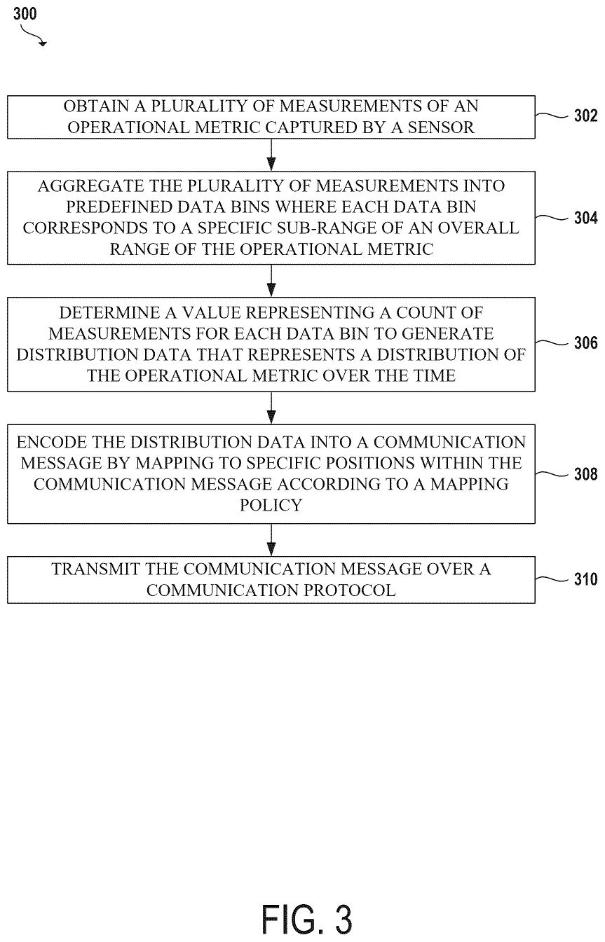

FIG. 3 presents a flow diagram illustrating an embodiment of a routine 300 implemented by the field device 110 of FIG. 1. The routine 300 outlines a process by which the device collects, organizes, and transmits temperature data while managing energy consumption and data communication within the constraints of its operating environment. Although described as being implemented by the field device 110, it will be understood that one or more elements outlined for routine 300 can be implemented by one or more computing devices or components that are associated with the system 100, such as the interpretation and management system 130. Thus, the following illustrative embodiment should not be construed as limiting.

At block 302, the field device 110 obtains a plurality of measurements of one or more operational metrics over time. These measurements are captured by a sensor 114 at intervals that can be determined by a schedule, policy, or algorithm. For example, the sensor 114 may capture measurements every X number of minutes, every X hour(s), and so forth. In some cases, the sensor 114 captures the measurements at hourly, daily, or weekly intervals. In some cases, the sensor 114 captures measurements asynchronously, such as when certain events are detected, allowing for real-time data collection in response to specific conditions.

The operational metric can vary across embodiments and can include, but is not limited to, temperature, flow rate, pressure, level, velocity, acceleration, or power usage. As an example, the sensor 114 can be a temperature sensor and might measure the temperature of the field device 110 itself, or the temperature of the battery of the field device 110, capturing data at hourly intervals to create a detailed temperature profile over time, where the expected range might be between −2° C. and 27° C. As another example, the sensor 114 can be a flow rate sensor in an irrigation system and might record flow rates ranging from 5 to 50 liters per minute, with measurements taken every 15 minutes to monitor water usage. As another example, the sensor 114 can be a pressure sensor in a gas pipeline and might capture pressure readings every minute, with an expected range between 1 and 10 bar. As another example, the sensor 114 can be used to monitor liquid levels in a storage tank, where it might capture level measurements every hour, with readings indicating levels between 0 and 100 meters. As another example, the sensor 114 can be used for velocity and/or acceleration monitoring in a transportation system, where it might capture velocity data every second with expected speeds between 0 and 100 km/h, and acceleration data between-10 and 10 m/s². As another example, the sensor 114 can be a power usage sensor within a smart grid, capturing power consumption data every 10 minutes, with readings typically ranging from 100 kW to 1 MW, providing insights into energy consumption patterns.

In some cases, the operational metric is a measure that typically remains within a given or expected range such that it generally exhibits stable, predictable fluctuations within defined limits. In some cases, the inventive concepts described herein may be well-suited for conveying this type of information because the information related to such operational metrics can be conveyed in the form of aggregated distribution data within a compact communication message, as described herein.

At block 304, the field device 110 aggregates the plurality of measurements into predefined data bins. Each data bin can correspond to a different sub-range within the overall range of the operational metric. Such an approach can include dividing an entire range of possible measurement values into smaller, specific intervals, with each interval represented by a data bin. For example, if the operational metric is temperature and the range is from −30° C. to 30° C., this range can be divided into smaller segments, such as −30° C. to −25° C., −25° C. to −20° C., and so on, with each segment representing a data bin. Each measurement can be assigned to the appropriate data bin according to the sub-range it corresponds to. For instance, a temperature reading of 22° C. can be placed in the 20° C. to 25° C. data bin. In some cases, this aggregation can be managed by the metric coordinator 116, which can organize the collected measurements into these discrete data bins based on the specific sub-range each measurement falls into.

In some cases, the size of the data bins may be uniform across the entire range of the operational metric. For example, if the operational metric is flow rate in a water distribution system, and the expected range is between 0 and 100 liters er minute, the metric coordinator 116 can define uniform data bins in 10-liter increments, such as 0-10 liters per minute, 10-20 liters per minute, 20-30 liters per minute, and so on. Each measurement can be assigned to the appropriate data bin according to the sub-range it corresponds to. For instance, a flow rate measurement of 22 liters per minute can be placed in the 20-30 liters per minute bin.

In some cases, the size of the data bins may not be uniform. For instance, the metric coordinator 116 can define smaller data bins for certain ranges and larger data bins for others. In some cases, the size of the data bins may vary depending on the distribution of the measurements. For instance, the metric coordinator 116 might adjust data bin sizes dynamically to reflect areas where measurements are more concentrated. For example, the metric coordinator 116 might define smaller increments for data bins in areas where measurements are densely concentrated, and larger increments in less concentrated areas. This approach can allow for detailed insights into specific ranges where the operational metric exhibits more variability. For example, if the temperature measurements frequently fall between 0° C. and 10° C., the metric coordinator 116 might define smaller data bins within this range, such as 0° C. to 2° C., 2° C. to 4° C., and so on, while using larger data bins outside this range.

In some cases, the field device 110 utilizes a weighted histogram approach to manage and compress temperature data for efficient communication. For example, a temperature range can be divided into specific bins, with each bin representing a sub-range of the overall temperature spectrum. The number of occurrences in each bin can be counted, and these counts can be reduced using a scalar factor, such as 2^5, before being encoded into the communication message.

The aggregation of data into data bins can occur in different ways depending on the application. In some cases, the aggregation might take place as the measurements are received in real-time or near-real-time, with each new measurement directly being assigned to the corresponding bin. In other cases, the aggregation might occur according to a schedule (e.g., every X minutes), or after a certain threshold number of measurements have been collected. For example, the field device 110 might accumulate measurements until just before a communication message is about to be sent. In some cases, this delay in aggregation can allow the metric coordinator 116 to dynamically select an appropriate data bin configuration based on the data received, tailoring the data bin sizes to ensure that the aggregated data effectively conveys the most relevant information. For instance, smaller data bins might be selected for ranges where data points are concentrated, thereby providing more granular insights into those specific values.

In some cases, the metric coordinator 116 might select from a set of predefined data bin configurations, choosing a configuration that is well suited for conveying the data collected. However, in some cases, the data bin configurations may not be predefined and can be dynamically generated based on the characteristics of the collected data. As described herein, as part of the communication message, the field device 110 can include a configuration identifier that conveys which data bin configuration was used. For example, the configuration identifier might be a specific code representative of a selected, predefined data bin configuration. In other cases, the configuration identifier might convey instructions or parameters that allow the receiver to determine how the selected configuration was applied. For example, the configuration identifier might indicate whether uniform or non-uniform data bins were used or specify the particular ranges associated with each data bin in the selected configuration. In some cases, the configuration identifier can convey whether the data bins were predefined or dynamically generated, the total number of data bins used, or adjustments made to bin sizes based on the concentration of data points within certain ranges.

In some cases, the data bins can be configured to hold different types of operational metrics, such as some bins storing temperature data and others storing pressure data. For example, the field device 110 can utilize a configuration identifier within the communication message to indicate the type of data stored in each bin. For example, a configuration identifier of ‘T’ can be used to denote that the bins contain temperature data, while ‘P’ can indicate that the bins contain pressure data. As another example, the mapping policy can be defined such that specific bins are allocated to different metrics, such as the first 10 bins holding pressure data and the next 10 bins holding temperature data. This approach allows the system to efficiently manage and transmit multiple types of operational data within a single communication message.

At block 306, the field device 110 can determine values associated with each data bin. These values can represent different aspects of the data depending on the application. For instance, in some cases, the values represent the number or count of measurements that fall within each data bin. In some cases, the values represent the relative distribution, such as the percentage of time the operational metric resides within each bin. Collectively, these values can form distribution data, which can reflect a statistical distribution of the operational metric over the monitored period. In some cases, this distribution data can provide an overview of how the operational metric has varied over time, offering valuable insights into the environmental conditions or operational patterns experienced by the field device 110.

The metric coordinator 116 can be responsible for counting the number of measurements that fall within each data bin. These counts can then be stored as part of the distribution data, effectively summarizing the frequency with which the operational metric falls within each sub-range. For instance, if the operational metric is temperature, the metric coordinator 116 might count how many temperature measurements were captured within each predefined bin. As an example, the field device 110 might record that 12000 measurements fell within the 0° C. to 5° C. bin, 20000 measurements fell within the 5° C. to 10° C. bin, and only 3000 measurements fell within the 10° C. to 15° C. bin.

In some cases, the field device 110 can be configured to track the frequency of specific events and categorize these events based on the operational metrics at the time they occurred. For example, the field device 110 can be configured to log the number of occurrences of an event within specific temperature ranges, such as recording the number of transmissions when the temperature was in the 0-10 degree range, 10-20 degree range, and so forth. This configuration can enable the field device 110 to monitor the relationship between environmental conditions, such as temperature, and the operational behavior of the device.

In some cases, the absolute number of measurements, frequency, etc. within each data bin may not be the primary focus. Rather, the relative distribution of the operational metric over time can be more relevant or desirable to determine. For example, in the context of battery life estimation, it may be more useful to know the percentage of time that the battery temperature resides within a particular range, rather than the exact number of counts. This percentage or relative distribution can be used to assess the overall thermal exposure of the battery, which can support predictions about its longevity. For instance, if the distribution data indicates that the battery temperature was within the 20° C. to 25° C. range 70% of the time, this information could be used for estimating the battery's remaining life.

In some cases, the field device 110 can generate or use a compression component to condense large values of the data so it can fit in the communication message. For example, the count for each data bin can be adjusted using a scalar component to efficiently encode the data. For example, if the actual count for a data bin is 87,600 measurements—such as might be collected from hourly data over a 10-year period—a scalar component of 2^ (or 1,024) might be applied. In this case, the stored count might be recorded as 85, with the scalar component being used later to reconstruct the original value. This approach not only reduces the amount of data that needs to be transmitted, particularly when dealing with very large numbers of measurements, but also allows for early determination of percentages or relative distributions while using less data. By encoding the data in this way, the field device 110 can efficiently convey significant information about the distribution of the operational metric, while still preserving the integrity of the original data.

The generated distribution data can reflect various operational metrics depending on the application. For example, if the operational metric is flow rate in an irrigation system, the distribution data might show that most flow rate measurements fell within the 20-30 liters per minute range, with fewer measurements in the 40-50 liters per minute range. Similarly, if the operational metric is pressure within a gas pipeline, the distribution data might reveal that the majority of pressure readings were within the 5-7 bar range, with occasional spikes in the 8-10 bar range.

In some cases, this distribution data can provide insights into the operational environment or conditions surrounding the field device 110, highlighting patterns and trends that can be used for further analysis, such as predicting maintenance needs, assessing performance, or adjusting operational parameters. By generating and storing the distribution data, the field device 110 can create a detailed statistical profile of the operational metric over time, allowing for informed decision-making based on actual measured conditions.

At block 308, the field device 110 encodes the distribution data into a communication message. The encoding process can be guided by a mapping policy, which in some cases, defines specific positions within the communication message for respective portions of the distribution data. The mapping policy can provide instructions on where each data bin's value is placed within the communication message, ensuring that the data can be decoded correctly by the receiving system.

The mapping policy can provide detailed guidelines on how to map the counts or values associated with each data bin into specific positions within the communication message. For example, the mapping policy might indicate that the value for the first data bin is placed in the first byte of the communication message, the value for the second data bin in the second byte, and so forth. This structured approach ensures that the distribution data is organized in a way that allows the receiving system to reconstruct it accurately.

In some cases, the mapping policy can assign a predetermined position within the communication message for a scalar identifier, which represents a scalar component used to scale the counts of measurements within each data bin. As described herein, scaling can be used to compress large counts into smaller values for transmission. The mapping policy might specify how these scaled values are placed within the communication message and how the receiving system can apply the corresponding scaling factors to decode the original counts. For example, if a scalar component of 2^ was applied to the counts, the mapping policy might include information that allows the receiver to recognize and reverse this scaling during decoding.

In some cases, the mapping policy can assign a predetermined position to a configuration identifier within the communication message, as described herein. Among other things, this configuration identifier can indicate how the data bins were configured, such as whether uniform or non-uniform bins were used, and can provide information on the specific ranges associated with each bin. The configuration identifier can allow a receiving system to accurately decode the communication message based on the configuration used during data aggregation.

In some cases, for example in addition to temperature data bins, the communication message may include extra bits (e.g., 4 bits), which can be used to encode one or more identifiers that denote the specific range set or bin configuration applied. This identifier allows the receiving system to correctly interpret the data, even when different bin configurations are used. This flexibility also enables the system to extend its data collection to other metrics, such as water pressure or flow rate, by simply adjusting the bin definitions and encoding parameters accordingly.

In some cases, the communication message may be limited or fixed in size, dictating the amount of data that can be included in a single transmission. For instance, the communication message might include 25 8-bit sections, designed to fit within the constraints of the communication protocol. The mapping policy, as described, can provide specific instructions on how each byte of the communication message is utilized, ensuring that the distribution data and any associated identifiers are accurately mapped to the appropriate positions within the communication message. This allows the field device 110 to efficiently convey the necessary data while adhering to the size limitations of the communication message.

At block 310, the field device 110 can transmit the communication message over a communication protocol managed by the communication system 118. The communication protocol can be a low-bandwidth, energy-efficient protocol, designed to operate within the constraints of the field device's environment.

The transmission of the communication message can occur at predetermined intervals, such as once per day or once per week, depending on the operational requirements. In some cases, the transmission may be event-driven, triggered by specific conditions such as a significant change in the operational metric, detection of an anomaly, or the accumulation of a certain volume of data. Alternatively, in some cases, the communication message may be added to a periodic transmission schedule, such as a monthly message rotation, to ensure the data is pushed at regular intervals without overloading the communication system.

Upon transmission, the communication message is received by the interpretation and management system 130, where it is processed and analyzed. The system can decode the distribution data from the communication message, applying the scalar component as necessary, and use this data for further analysis. This might include monitoring trends in the operational metric, assessing system performance, or making decisions based on the operational conditions experienced by the field device 110.

It will be appreciated that the same or a similar methodology can be applied to other operational metrics, such as those that fluctuate within defined ranges, such as water pressure, flow rate, or energy usage. The system's ability to dynamically adjust bin configurations and utilize a flexible mapping policy can allow it to be tailored to a variety of applications, providing accurate and actionable data across different domains. In some cases, certain bins may represent values outside of the typically defined range. For example, a first bin may capture values below the expected range, while a last bin may capture values above it. This can allow the system to account for extreme or unexpected conditions without limiting the overall range of data that can be analyzed.

### Processing and Analyzing Operational Metrics in Remote Systems

In distributed monitoring systems, such as those utilized in utility management and environmental monitoring, remote systems can be configured to process and analyze data received from a network of field devices. These field devices may be deployed in remote or resource-limited environments, requiring the remote systems to extract insights from the data while reducing the frequency of high-bandwidth communications. The interpretation and management system 130 can serve as a central hub for processing data received from multiple field devices. The system can be configured to analyze the data to monitor device performance, predict maintenance needs, and adjust operational parameters to support the efficiency and longevity of the deployed devices.

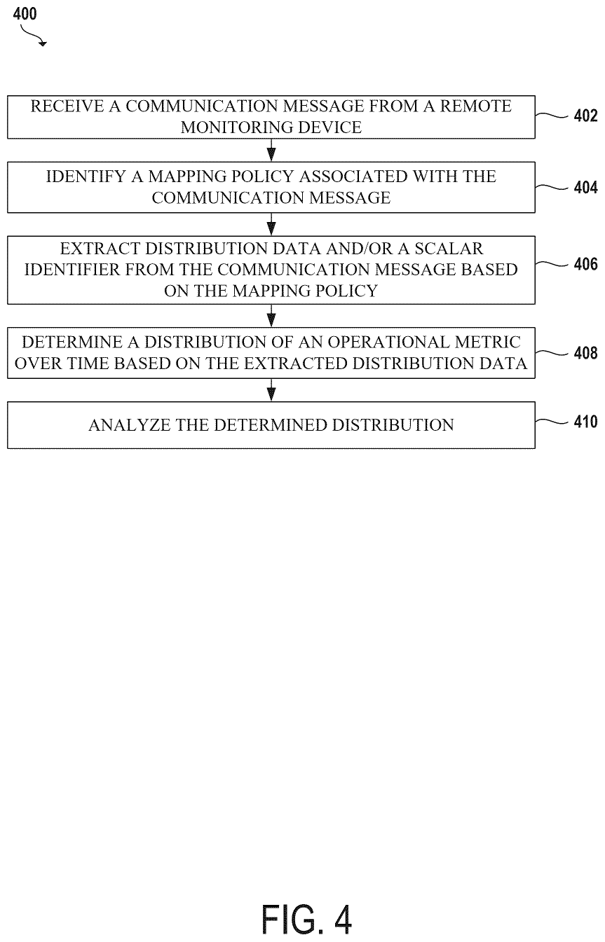

FIG. 4 presents a flow diagram illustrating an embodiment of a routine 400 implemented by the interpretation and management system 130 of FIG. 1. The routine 400 outlines a process by which the interpretation and management system 130 receives, decodes, and analyzes communication messages containing distribution data from field devices. Although described as being implemented by the interpretation and management system 130, it will be understood that one or more elements outlined for routine 300 can be implemented by one or more computing devices or components that are associated with the system 100, such as the field device 110. Thus, the following illustrative embodiment should not be construed as limiting.

At block 402, the interpretation and management system 130 can receive a communication message from a field device 110 via the network 102. The communication message can include encoded distribution data that represents an operational metric, such as temperature, pressure, flow rate, or any other environmental or operational parameters that have been monitored by the field device 110 or an associated sensor 114. This distribution data can have been previously collected, aggregated, and processed by the field device 110 as described herein, for example with respect to FIG. 3. The communication message received at block 402 can correspond to the communication message sent at block 310 of FIG. 3.

A communication system 132 within the interpretation and management system 130 can be configured to handle the reception of these messages under various operational conditions. Once the communication message is received, the interpretation and management system 130 can store the communication message at least temporarily or process it immediately, depending on the operational requirements. In some cases, the interpretation and management system 130 may prioritize certain messages based on their content or the urgency of the data they contain, such as messages indicating a significant deviation in the operational metric or a potential anomaly that requires immediate attention.

At block 404, the interpretation and management system 130 identifies a mapping policy associated with the received communication message. As described herein, the mapping policy defines the specific positions within the communication message where the distribution data for each data bin is stored, along with any scalar identifiers or other metadata.

In some cases, the communication message may include an identifier that specifies the mapping policy used by the field device 110. This identifier can be a unique code or a set of bits within the communication message that corresponds to a particular mapping policy. The interpretation and management system 130 can use this mapping policy identifier to determine the correct mapping policy from a set of predefined mapping policies stored within the system. In some cases, each predefined mapping policy in the set can be tailored to different configurations of the field device 110, such as varying ranges of operational metrics, different bin configurations, or distinct scaling factors. The mapping policy identifier can allow the interpretation and management system 130 to quickly and accurately select the appropriate mapping policy, ensuring that the distribution data and any associated metadata are decoded correctly. For example, the identifier might correspond to a mapping policy that applies to a specific range of temperatures, a particular arrangement of data bins, or a unique method of scaling the bin counts. By referencing the mapping policy associated with the identifier, the system can adapt to different data formats and configurations, providing flexibility in how the data is processed and interpreted.

In some cases, the interpretation and management system 130 may automatically use a predefined mapping policy that is shared with the field device 110. This predefined mapping policy can be stored in both the field device 110 and the interpretation and management system 130, allowing for consistent encoding and decoding of the distribution data. In some cases, this allows for consistent encoding and decoding without requiring an identifier in the communication message.

At block 406, the interpretation and management system 130 can be configured to extract the distribution data from the communication message based on the identified mapping policy. This extraction process can include retrieving the values from their assigned positions within the communication message, as delineated by the mapping policy. In instances where a scalar identifier is included within the communication message, the scalar identifier can be utilized to apply a scaling factor to the extracted values, thereby reconstructing the original counts or measurements associated with each data bin.

In some cases, if the communication message includes a configuration identifier, the configuration identifier can provide information regarding the configuration of the data bins during the aggregation process. This can include, but is not limited to, whether the data bins were uniformly or non-uniformly distributed, the specific ranges associated with each data bin, and any other pertinent configuration parameters. The mapping policy can guide the interpretation and management system 130 in identifying and correctly interpreting these identifiers when present.

Upon application of the mapping policy, the interpretation and management system 130 can align the extracted data in accordance with the structure specified by the mapping policy. This process can facilitate accurately interpretation of the communication message in a manner consistent with their original encoding. As a result, the system can reliably reconstruct the distribution of the operational metric over the monitored period, thereby facilitating accurate analysis and decision-making based on the received data.

At block 410, the interpretation and management system 130 can analyze the determined distribution of the operational metric to assess operational conditions, predict maintenance requirements, or adjust operational parameters for the field device 110. For example, if the operational metric is the temperature of the battery in the field device 110, the interpretation and management system 130 can use the distribution of temperature measurements over time to estimate the remaining battery life.

This analysis can include evaluating how frequently and for how long the battery has operated within specific temperature ranges. Since battery performance can be influenced by temperature exposure, the interpretation and management system 130 can apply models that correlate the observed temperature distribution with battery degradation rates. If the temperature distribution shows that the battery has frequently been exposed to higher temperatures, the interpretation and management system 130 might estimate a shorter remaining battery life. Conversely, if the battery has mostly operated within an optimal temperature range, the interpretation and management system 130 could predict a longer remaining lifespan.

This approach can allow the interpretation and management system 130 to recommend adjustments to the field device's operational parameters, such as reducing the duty cycle to mitigate further wear on the battery. Additionally, the interpretation and management system 130 can predict when battery replacement might be needed, allowing for proactive maintenance scheduling to avoid unexpected downtime and extend the overall service life of the field device 110.

### EXAMPLE EMBODIMENTS

In various embodiments, the field device 110 of FIG. 1 can implement different strategies for encoding and transmitting operational metrics, depending on the level of flexibility desired for defining data bins. These strategies can range from using predefined bins to dynamically adjusting bin configurations during operation, each offering different benefits in terms of message structure, adaptability, and interpretability by the interpretation and management system 130. The following examples illustrate example different approaches, demonstrating how the metric coordinator 116 can adjust the encoding process according to the specific needs of the application.

### Example 1: Predefined Bins

In some embodiments, the field device 110 can operate using a predefined bin configuration where both the ranges and their positions in the communication message are established and understood in advance. This approach can provide an efficient way to transmit aggregated data with a structured message format. The interpretation and management system 130 can interpret the communication message based on the predefined mapping of ranges to specific positions within the communication message.

Consider a first scenario in which the field device 110 operates under a predefined bin configuration. In this example, the field device 110 utilizes a predetermined set of temperature ranges that have been established before the operation begins. This configuration specifies that each byte in the communication message corresponds to a specific temperature range: for instance, the first byte is designated for temperatures between 0 to 10 degrees (Range A), the second byte for temperatures between 10 to 13 degrees (Range B), the third byte for temperatures between 13 to 15 degrees (Range C), and so on. The communication message generated by the field device 110 includes counts that correspond to each of these predefined ranges. For example, a communication message might be structured as ‘10, 4, 0, 10,’ where the first ‘10’ represents 10 counts in Range A (0 to 10 degrees), the ‘4’ represents 4 counts in Range B (10 to 13 degrees), the ‘0’ represents 0 counts in Range C (13 to 15 degrees), and the last ‘10’ represents 10 counts in Range D (above 15 degrees). The metric coordinator 116 within the field device 110 can aggregate the temperature measurements into these predefined bins and encode the resulting counts according to the established ranges, as dictated by the mapping policy. The mapping policy ensures that each count is encoded in the correct position within the message, corresponding to its associated temperature range.

Upon receiving the communication message, the interpretation and management system 130 can decode the message using the predefined mapping policy, which specifies the association between each position in the message and a specific temperature range. The mapping policy ensures that the system knows which temperature range each position in the message corresponds to. For example, in this case, the system would interpret ‘10’ in the first position as representing 10 counts in Range A (0 to 10 degrees), ‘4’ in the second position as representing 4 counts in Range B (10 to 13 degrees), ‘0’ in the third position as representing 0 counts in Range C (13 to 15 degrees), and ‘10’ in the fourth position as representing 10 counts in Range D (above 15 degrees). This scenario demonstrates an implementation where both the temperature ranges and their specific positions within the communication message are predetermined and understood by both the field device 110 and the interpretation and management system 130 before data collection and transmission.

### 2: Predefined Range Names With Variable Message Locations

In another embodiment, the field device 110 can transmit communication messages where an identifier of each range is included within the message itself. This configuration can allow for variability in which temperature ranges are reported while maintaining the use of predefined range names. The predefined names can correspond to specific temperature ranges, but the communication message can allow flexibility in including only those ranges that include relevant data. This method can result in more efficient data transmission, particularly when certain ranges do not require reporting.

Consider a second scenario in which the field device 110 transmits communication messages that include both the name of each range and the associated count. In this embodiment, while the names of the temperature ranges are predefined, the specific ranges that are included in each message can vary depending on the data collected. For instance, the communication message might be structured as ‘A, 10, B, 4, D, 10,’ where ‘A’ represents the 0 to 10 degrees range, ‘B’ represents the 10 to 13 degrees range, and ‘D’ represents the 20 to 25 degrees range. The metric coordinator 116 within the field device 110 aggregates the temperature measurements into these specified bins and then encodes both the range name and its corresponding count into the communication message.

Upon receiving the communication message, the interpretation and management system 130 decodes the message by first reading the range name, followed by the count associated with that range. The mapping policy ensures that the system accurately interprets each part of the message. For example, in this case, the system would interpret ‘A, 10’ as representing 10 counts in the 0 to 10 degrees range, ‘B, 4’ as representing 4 counts in the 10 to 13 degrees range, and ‘D, 10’ as representing 10 counts in the 20 to 25 degrees range. Any ranges not mentioned in the communication message, such as the range ‘C’ (13 to 20 degrees), would be assumed to have a count of zero. This scenario demonstrates an implementation where the names of the temperature ranges are predefined, but the message structure allows for variability in which ranges are reported, optimizing communication efficiency based on the actual data collected.

### 3: Passing Actual Range Values with Counts

In some embodiments, the field device 110 can transmit communication messages where the actual range values are passed along with the corresponding counts. This method allows for dynamic adjustment of bins during operation, providing flexibility to the system to encode data based on real-time conditions without being restricted by predefined ranges. Although this approach may result in longer messages, it enables a more detailed and accurate representation of the operational metrics, accommodating a wide variety of measurement scenarios.

Consider a third scenario where the field device 110 includes the actual start and end values of each range within the communication message, along with the count for that range. For instance, a message might be structured as ‘0, 10, 10, 10, 13, 4,’ where the first byte (‘0’) represents the start of the first range, the second byte (‘10’) represents the end of the first range, and the third byte (‘10’) represents the count of measurements within that range. This would mean that there were 10 counts in the 0 to 10 degrees range. Similarly, the next sequence ‘10, 13, 4’ would indicate that there were 4 counts in the 10 to 13 degrees range. The metric coordinator 116 within the field device 110 can dynamically construct these bins based on the real-time data it collects and then encode both the range values and counts into the communication message. This approach allows the system to adapt to varying data conditions without being confined to a fixed set of ranges.

Upon receiving the communication message, the interpretation and management system 130 decodes the message by reading each set of three bytes, interpreting the first two bytes as the start and end values of the range, and the third byte as the count. For example, the system would understand ‘0, 10, 10’ as 10 counts in the 0 to 10 degrees range and ‘10, 13, 4’ as 4 counts in the 10 to 13 degrees range. This method provides the flexibility to accommodate various range configurations and is useful in scenarios where the operational environment may change dynamically. A variation of this approach might include omitting the end range value if the subsequent start value implicitly serves as the end of the previous range. For example, ‘0, 10, 10, 4, 13’ could encode the same data more efficiently, with the final value (‘13’) acting as a terminator for the last range. This method of encoding ensures that the interpretation and management system 130 can accurately reconstruct the operational metrics from the transmitted data, regardless of the variability in the range definitions.

These scenarios demonstrate example versatility of the field device 110 in adapting its data encoding and transmission strategy based on the available bandwidth and the specific requirements of the monitoring application. Each scenario aligns with the operational steps outlined in routine 300, where the metric coordinator 116 dynamically determines the appropriate bin configuration, aggregates the data, and encodes it into the communication message for transmission by the communication system 118.

### Terminology

Although this disclosure has been described in the context of certain embodiments and examples, it will be understood by those skilled in the art that the disclosure extends beyond the specifically disclosed embodiments to other alternative embodiments and/or uses and obvious modifications and equivalents thereof. In addition, while several variations of the embodiments of the disclosure have been shown and described in detail, other modifications, which are within the scope of this disclosure, will be readily apparent to those of skill in the art. It is also contemplated that various combinations or sub-combinations of the specific features and aspects of the embodiments may be made and still fall within the scope of the disclosure. For example, features described above in connection with one embodiment can be used with a different embodiment described herein and the combination still fall within the scope of the disclosure. It should be understood that various features and aspects of the disclosed embodiments can be combined with, or substituted for, one another in order to form varying modes of the embodiments of the disclosure. Thus, it is intended that the scope of the disclosure herein should not be limited by the particular embodiments described above. Accordingly, unless otherwise stated, or unless clearly incompatible, each embodiment of this invention may include, additional to its essential features described herein, one or more features as described herein from each other embodiment of the invention disclosed herein.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described in the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately,” “about,” “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, 0.1 degree, or otherwise.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A system comprising a device, the device comprising a processor configured to:
obtain a plurality of measurements of an operational metric captured by a sensor, wherein the sensor captures the plurality of measurements over time, and wherein the plurality of measurements fall within an overall range for the operational metric;
aggregate the plurality of measurements into data bins, each data bin corresponding to a different sub-range of the overall range of the operational metric, wherein each measurement is assigned to a respective data bin based on a respective sub-range it corresponds to;
determine a value representing a count of measurements for each data bin, thereby generating distribution data that represents a distribution of the operational metric over the time;
encode the distribution data into a communication message by mapping portions of the distribution data to specific positions within the communication message according to a mapping policy, wherein the mapping policy assigns a different predetermined position in the communication message to the respective distribution data of each data bin, such that the value for each data bin is assigned to a unique position within the communication message; and
make the communication message available for transmission or retrieval, wherein the distribution of the operational metric over the time can be determined based on the communication message and the mapping policy.

2. The system of claim 1, wherein the operational metric is at least one of temperature, flow rate, pressure, level, velocity, acceleration, power, or usage patterns.

3. The system of claim 1, wherein the processor is further configured to dynamically adjust the data bins based on a concentration of measurements within specific sub-ranges of the overall range for the operational metric.

4. The system of claim 1, wherein there are multiple configurations of data bins, each configuration corresponding to different predefined ranges for the operational metric, wherein the processor is further configured to select a configuration of data bins based on the plurality of measurements, and encode a configuration identifier of the selected configuration into the communication message based on the mapping policy.

5. The system of claim 1, wherein the processor is further configured to encode the distribution data into the communication message based on a predefined bin configuration, wherein the predefined bin configuration specifies that ranges of the operational metric and their corresponding positions within the communication message are established before the processor begins encoding the distribution data.

6. The system of claim 1, wherein each data bin is assigned to a different location within the communication message, such that the value representing the measurements for each data bin is stored in a unique location of the communication message.

7. The system of claim 1, wherein the communication message includes a configuration identifier, and the processor is configured to encode the configuration identifier within the communication message, specifying whether the predefined data bins are uniform or non-uniform.

8. The system of claim 1, wherein the processor is further configured to include, within the communication message, an identifier corresponding to each predefined range of the operational metric and a corresponding count, wherein specific ranges included in the communication message vary based on data collected.

9. The system of claim 1, wherein the processor is further configured to encode at least one of actual start values or actual end values of each range of the operational metric within the communication message, along with a corresponding count for each range.

10. The system of claim 9, wherein the communication message includes a sequence of values, where each sequence of values encodes at least one of a start value or an end value, and a count for each range of the operational metric.

11. The system of claim 1, further comprising a battery configured to provide power to a device for an extended duration without recharge, wherein the operational metric relates to a remaining life of the battery, and wherein the remaining life of the battery is estimated based at least in part on the communication message.

12. The system of claim 1, wherein the processor is further configured to assign multiple different types of operational metrics to specific data bins within the communication message, and to encode a configuration identifier that specifies a type of operational metric stored in each data bin, allowing for transmission of multiple different operational metrics in a single communication message.

13. A method, comprising:
obtaining a plurality of measurements of an operational metric captured by a sensor, wherein the sensor captures the plurality of measurements over time, and wherein the plurality of measurements fall within an overall range for the operational metric;
aggregating the plurality of measurements into predefined data bins, each data bin corresponding to a different sub-range of the overall range of the operational metric, wherein each measurement is assigned to a respective data bin based on a respective sub-range it corresponds to;
determining a value representing a count of measurements for each data bin, thereby generating distribution data that represents a distribution of the operational metric over the time;
encoding the distribution data into a communication message by mapping portions of the distribution data to specific positions within the communication message according to a mapping policy, wherein the mapping policy assigns a different predetermined position in the communication message to the respective distribution data of each data bin, such that the value for each data bin is assigned to a unique position within the communication message; and
transmitting the communication message over a communication protocol, wherein the distribution of the operational metric over the time can be determined based on the communication message and the mapping policy.

14. The method of claim 13, further comprising dynamically adjusting the predefined data bins based on a concentration of measurements within specific sub-ranges of the overall range for the operational metric.

15. The method of claim 13, further comprising selecting a configuration of data bins from multiple configurations, each configuration corresponding to different predefined ranges for the operational metric, and encoding a configuration identifier of the selected configuration into the communication message based on the mapping policy.

16. The method of claim 13, further comprising assigning multiple different types of operational metrics to specific data bins within the communication message, and encoding a configuration identifier that specifies the type of operational metric stored in each data bin, thereby allowing for transmission of multiple different operational metrics in a single communication message.

17. A method for processing received operational metrics, the method comprising:
receiving a communication message from a field device, wherein the communication message corresponds to aggregated distribution data representing a plurality of measurements of an operational metric captured by the field device, the measurements having been aggregated into predefined data bins, each data bin corresponding to a sub-range of an overall range of the operational metric;
identifying a mapping policy associated with the communication message, wherein the mapping policy defines specific positions within the communication message for respective portions of the distribution data;
extracting the distribution data and the scalar identifier from the communication message based on the mapping policy, wherein a value of each data bin is obtained from an assigned position within the communication message;
determining the distribution of the operational metric over time based on the extracted distribution data and the respective sub-ranges of the data bins; and
analyzing the determined distribution to assess operational conditions, predict maintenance requirements, or adjust operational parameters for the field device.

18. The method of claim 17, wherein the distribution data corresponds to a temperature of a field device, and further comprising using the distribution data to determine an expected remaining battery life of the field device.

19. The method of claim 17, wherein the mapping policy includes a configuration identifier, the method further comprising identifying a configuration of data bins in the communication message based on the configuration identifier, wherein the configuration identifier specifies at least one of a structure or an arrangement of the data bins.

20. The method of claim 17, further comprising adjusting interpretation of the distribution data based on a compression component identified within the communication message, wherein the compression component is applied to the values to reconstruct an original count of measurements for each data bin.
